(19) United States
(12) Patent Application Publication
(10) Pub. No.: US 2008/0173427 A1
(43) Pub. Date: Jul. 24, 2008

(54) Electronic component cooling

(76) Inventor: Richard Schumacher, Dallas, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/656,776

(22) Filed: Jan. 23, 2007

(51) Int. Cl. F28D 15/00; H05K 7/20

(52) U.S. Cl. 165/104.14; 361/699

(57) ABSTRACT

An electronic assembly incorporates a sealed chamber that is filled with a first cooling fluid. A second cooling fluid that does not contact the first cooling fluid is circulated so as to remove heat from the first cooling fluid. The second cooling fluid is transported to an external heat removal system. Fluid circulation apparatus circulates the first cooling fluid within the chamber and facilitates heat transfer from components in the chamber. Optionally, the second cooling fluid may provide power to circulate the first cooling fluid.

### BACKGROUND

The present invention relates to electronic component cooling systems and methods.

Electronic devices often require cooling. If such devices are to operate within an enclosure, such as an electromagnetic interference (EMI) enclosure, for example, heat must be removed in some way that does not compromise the enclosure. Multiple devices may also be packaged in an electronic assembly at high density which inhibits heat removal directly to ambient air.

Conventional conductive cooling elements are typically attached to one surface of each component that is to be cooled. Using only one surface results in a high heat flux in the heat removal path that can create large temperature gradients. These gradients can result in high temperatures within components, and/or a lower temperature requirement for heat rejection, and/or thermal stresses in components.

To ensure adequate thermal contact, the location of each attachment surface must be well controlled, the heat removal path must mechanically accommodate variable surface locations, a conductive contact/bridging material must be used, or some combination of the above must be used. These can be expensive to fabricate and/or difficult to assemble.

Other approaches may spray a liquid coolant onto each device requiring cooling. These are specific to the arrangement of devices to be cooled and typically remove heat through only one surface of each device.

Existing cooling solutions developed by the assignee of the present invention are disclosed in U.S. Pat. Nos. 6,867,976, 6,819,562, 6,695,042, 6,625,026, and 6,580,610.

It would be desirable to have improved cooling systems and methods for use in cooling electronic assemblies, and the like.

### BRIEF DESCRIPTION OF THE DRAWINGS

The various features and advantages of disclosed embodiments may be more readily understood with reference to the following detailed description taken in conjunction with the accompanying drawings, wherein like reference numerals designate like structural elements, and in which:

FIG. 1 illustrates a first embodiment of electronic apparatus comprising an exemplary active cooling system; and

FIG. 2 illustrates a second embodiment of electronic apparatus comprising another exemplary active cooling system; and

FIG. 3 is a flow diagram that illustrates an exemplary cooling method.

### DETAILED DESCRIPTION

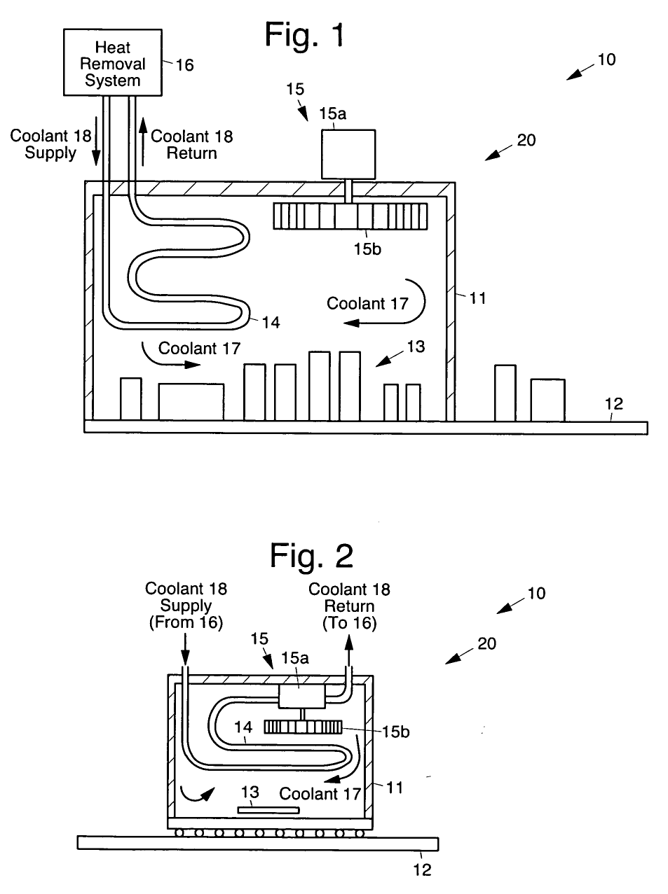

Referring to the drawing figures, FIG. 1 illustrates a first embodiment of electronic apparatus 10 comprising an exemplary active cooling system 20. The electronic apparatus 10 comprises a printed circuit board 12 having a sealed enclosure 11 or sealed chamber 11 disposed thereon in which one or more electronic components 13 are housed.

A first coolant 17 or first cooling fluid 17 is disposed within the sealed chamber 11. The first cooling fluid 17 contacts exposed surfaces of, or bathes, each of the electronic components 13 disposed within the sealed chamber 11. The first cooling fluid 17 is adapted to remove heat generated within the sealed chamber 11 by the one or more electronic components 13.

The exemplary active cooling system comprises one or more fluid circulators 15, such as pumps 15 or fans 15, for example, that circulate the first cooling fluid 17 within the sealed chamber 11. An exemplary fluid circulator 15 may comprise a drive motor 15a disposed exterior to the sealed chamber 11 that is coupled to a fan 15b or impeller 15b disposed within the sealed chamber 11. In other applications the drive motor 15a may be disposed internal to the sealed chamber. In either case the drive motor 15a may be coupled to the fan or impeller 15b mechanically or magnetically.

The exemplary active cooling system comprises a heat exchanger 14 disposed within the sealed chamber 11. The heat exchanger 14 is illustrated as a tube or coil that may be located inside the sealed chamber 11 or may be embedded within the walls of the sealed chamber 11. The heat exchanger 14 is coupled to a heat removal system 16 that is external to the sealed chamber 11. A second cooling fluid 18 flows through the heat exchanger 14 that is used to remove heat from the first coolant fluid 17 and couple it to the external heat removal system 16.

Thus, the exemplary cooling system 20 comprises a sealed chamber 11 filled with a first cooling fluid 17, which bathes all components 13 within the chamber 12. The first cooling fluid 17 is circulated using the one or more pumps 15 or fans 15, as appropriate to enhance removal of heat from the components 13 within the sealed chamber 11. Multiple pumps or fans 15 may be used for redundancy. The heat exchanger 14 is provided to transfer heat from the first cooling fluid 17 to the second coolant fluid 18 which is supplied from and coupled to the external heat removal system 16.

The first and second cooling fluids 17, 18 thus have different functions, and they are not allowed to mix with each other. The first and second cooling fluids 17, 18 may be the same substances, or may be different substances each optimized for its function in the application. For example the first cooling fluid may be selected for such properties as chemical compatibility with the devices to be cooled and low vapor pressure in the intended operating temperature range, whereas the second cooling fluid may be selected for such properties as low cost and low toxicity. Exemplary first cooling fluids include Fluorinert™, available from Minnesota Mining and Manufacturing Co. (3M), for example. Exemplary second fluids include deionized water, for example.

FIG. 2 illustrates a second embodiment of electronic apparatus comprising another exemplary active cooling system. As is illustrated in FIG. 2, optionally, each pump/fan 15 may be driven by a fluid motor 15a (that rotates the turbine 15b or impeller 15b, for example) that is driven by the second coolant fluid 18. FIG. 2 shows an application in which the chamber 11 comprises a package 13 comprising an integrated circuit chip 13 or die 13. As is shown in FIG. 2, the die 13 is the only device that is cooled. In this application the pump drive motor 15a is disposed internal to the sealed chamber 11 and coupled to the turbine or fan 15b mechanically via a drive shaft. In other applications the drive motor 15a may be disposed external to the sealed chamber. In some applications the drive motor 15a and turbine or fan 15b may be coupled magnetically.

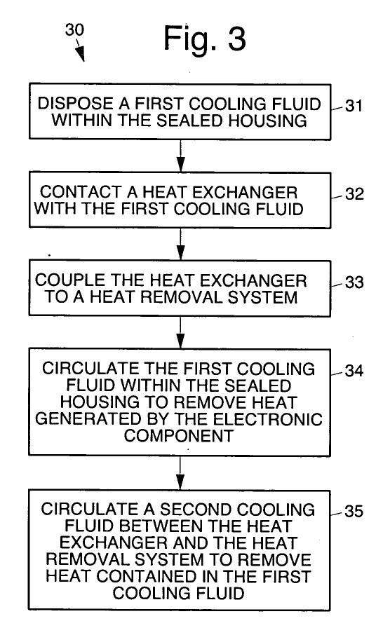

FIG. 3 is a flow diagram that illustrates an exemplary cooling method 30. The exemplary cooling method 30 may be used with an electronic assembly 13 comprising an electronic component 13 disposed within a sealed housing 11 or enclosure 11.

In implementing the exemplary cooling method 30 a first cooling fluid is disposed 31 within the sealed housing 11. A heat exchanger 14 is configured to contact 32 the first cooling fluid. The heat exchanger 14 is coupled to an external heat removal system 16. The first cooling fluid 17 is circulated within the sealed housing 11 to remove heat generated by the electronic component 13. A second cooling fluid 18 is circulated between the heat exchanger 14 and the heat removal system 16 to remove heat contained in the first cooling fluid 17.

Advantages of the disclosed cooling systems 20 and methods 30 are that heat is removed from all available surfaces of each component 13, thus removing more heat for a given temperature differential and reducing thermal gradients in the components 13. Furthermore, the use of fluid motors 15a to drive the internal pumps/fans 15 eliminates a local source of electromagnetic interference (EMI) and additional waste heat, as would exist with electric motors.

Thus, cooling systems have been disclosed. It is to be understood that the above-described embodiments are merely illustrative of some of the many specific embodiments that represent applications of the principles described herein. Clearly, numerous and other arrangements can be readily devised by those skilled in the art without departing from the scope of the invention.

What is claimed is:

1. Electronic component cooling comprising:
an electronic component disposed within a sealed enclosure;
a first cooling fluid disposed within the sealed enclosure that contacts exposed surfaces of the component;
a fluid circulator that circulates the first cooling fluid within the sealed enclosure; and
a heat exchanger that contacts the first cooling fluid and that contains a second cooling fluid.

2. The apparatus recited in claim 1 further comprising:
an external heat removal system coupled to the heat exchanger.

3. The apparatus recited in claim 1 wherein the fluid circulator comprises:
a drive motor disposed exterior to the sealed enclosure that is coupled to a pump or fan disposed within the sealed enclosure.

4. The apparatus recited in claim 1 wherein the fluid circulator comprises:
a drive motor disposed within the sealed enclosure that is coupled to a pump or fan disposed within the sealed enclosure, and wherein the second cooling fluid is coupled to the drive motor to operate the pump or fan.

5. Electronic apparatus comprising:
a printed circuit board comprising a sealed enclosure;
one or more electronic components disposed within the sealed enclosure;
a first cooling fluid disposed within the sealed enclosure;
a fluid circulator that circulate the first cooling fluid within the sealed enclosure; and
a heat exchanger that comprises a second cooling fluid that does not directly contact the first cooling fluid for removing heat from the first cooling fluid.

6. The apparatus recited in claim 5 first cooling fluid an external heat removal system coupled to the heat exchanger.

7. The apparatus recited in claim 5 wherein the fluid circulator comprises:
a drive motor disposed outside the sealed enclosure that is coupled to a pump or fan disposed inside the sealed enclosure.

8. The apparatus recited in claim 5 wherein the fluid circulator comprises:
a drive motor disposed within the sealed enclosure that is coupled to a pump or fan disposed within the sealed enclosure, and wherein the second cooling fluid is coupled to the drive motor to operate the pump or fan.

9. An electronic component cooling method for use with an electronic assembly having an electronic component disposed within a sealed housing, the method comprising:
disposing a first cooling fluid in the sealed housing;
circulating the first cooling fluid within the sealed housing to extract heat from the electronic component;
circulating a second cooling fluid that does not directly contact the first cooling fluid within the sealed housing to transfer heat from the first cooling fluid to the second cooling fluid; and
transporting the second cooling fluid outside of the sealed housing to remove heat from the second cooling fluid.

10. The method recited in claim 9 wherein circulating a second cooling fluid comprises:
contacting the first cooling fluid with a heat exchanger;
coupling the heat exchanger to an external heat removal system;
circulating a second cooling fluid between the heat exchanger and the heat removal system to remove heat contained in the first cooling fluid.

11. The method recited in claim 9 wherein circulating the first cooling fluid comprises:
disposing a pump or fan within the sealed housing;
coupling a drive motor to the pump or fan; and
operating the drive motor to circulate the first cooling fluid within the sealed housing.

12. The method recited in claim 9 wherein circulating the first cooling fluid comprises:
disposing a drive motor that is coupled to a pump or fan within the sealed housing; and
powering the drive motor using the second cooling fluid.
